(19) United States
(12) Patent Application Publication
(10) Pub. No.: US 2022/0091780 A1
(43) Pub. Date: Mar. 24, 2022

(54) MEMORY ACCESS METHOD AND INTELLIGENT PROCESSING APPARATUS

(71) Applicant: SigmaStar Technology Ltd., Fujian (CN)

(72) Inventors: Jianzhi WANG, Shanghai (CN); Wei ZHU, Shanghai (CN); Bingjie HE, Shanghai (CN); Bo LIN, Shanghai (CN); Mingyong SUN, Shanghai (CN)

(21) Appl. No.: 17/393,444

(22) Filed: Aug. 4, 2021

(30) Foreign Application Priority Data
Sep. 18, 2020 (CN) 202010990240.6

(51) Int. Cl. G06F 3/06

(52) U.S. Cl. CPC G06F 3/0655; G06F 3/0673; G06F 3/0604

(57) ABSTRACT

The disclosure provides an intelligent processing apparatus including a processor and a direct memory access (DMA) controller. The processor generates a read command to read data from a memory. An address generation circuit generates multiple first address signals to the memory. A data processing circuit receives data that the memory outputs in response to the multiple first address signals, and performs a data interception process on the data received from the memory according to the read command and a first configuration parameter. A data port transmits the data processed by the data processing circuit to the processor. The multiple first address signals include multiple non-consecutive address signals such that the data read from the memory and processed by the data processing circuit corresponds to n-dimensional data blocks, where n is a positive integer greater than 1.

This application claims the benefit of China application Serial No. CN202010990240.6, filed on Sep. 18, 2020, the subject matter of which is incorporated herein by reference.

### BACKGROUND OF THE INVENTION

### Field of the Invention

The disclosure relates to a memory access technique, and more particularly to a memory access method and an intelligent processing apparatus.

### Description of the Related Art

Current electronic devices such as smartphones and personal computers all include memories, for example, random access memories (RAM), for storing data. Data stored in a memory is usually access by an electronic device in a sequential manner during access, that is, consecutive addresses in a memory are sequentially accessed in a single access mode, in a way that the transmission efficiency and flexibility of the memory are quite limited

### SUMMARY OF THE INVENTION

In view of the issues of the prior art, it is an object of the disclosure to provide a memory access method and an intelligent processing apparatus so as to improve the prior art.

The disclosure provides a memory access method applied to an intelligent processing apparatus. The memory access method includes: determining a memory access mode; obtaining a data bit length parameter according to the memory access mode, the data bit length parameter including a data read/write bit length and a data transmission bit length; obtaining a memory access parameter of a memory space, the memory access parameter including a data transmission length and an address hop length; and accessing the memory space according to the data read/write bit length, the data transmission bit length, the data transmission length and the address hop length.

The disclosure further provides an intelligent processing apparatus. The intelligent processing apparatus includes: a processor, generating a read command to read data from a memory; and a direct memory access (DMA) controller, reading data from the memory according to the read command. The DMA controller includes: a configuration circuit, providing a first configuration parameter according to a first operation mode; a signal port, receiving the read command; an address generation circuit, generating a plurality of first address signals to the memory according to the first configuration parameter and the read command; a data processing circuit, receiving data that the memory outputs in response to the first address signals, and performs a data interception process on the data received from the memory according to the read command and the first configuration parameter; and a data port, outputting the data processed by the data processing circuit to the processor. The first address signals include a plurality of non-consecutive address signals such that the data read from the memory and processed by the data processing circuit corresponds to n-dimensional data blocks, where n is a positive integer greater than 1.

The disclosure further provides a memory access method applied to an intelligent processing apparatus. The intelligent processing apparatus includes a processor. The method access method includes: receiving a read command from the processor to read data from the memory; providing a first configuration parameter according to a first operation mode; generating a plurality of first address signals according to the first configuration parameter and the read command; and receiving data that the memory outputs in response to the first address signals, and performing a data interception process on the data received from the memory according to the read command and the first configuration parameter to output to the processor. The first address signals include a plurality of non-consecutive address signals such that the data read from the memory and processed by the data processing circuit corresponds to n-dimensional data blocks, where n is a positive integer greater than 1.

Features, implementations and effects of the disclosure are described in detail in preferred embodiments with the accompanying drawings below.

### BRIEF DESCRIPTION OF THE DRAWINGS

FIG. 1 is a structural schematic diagram of a chip applied to an electronic device according to an embodiment of the disclosure;

FIG. 2 is a block diagram of an intelligent processing apparatus according to an embodiment of the disclosure;

FIG. 3 is a first flowchart of a memory access method according to an embodiment of the disclosure; and

FIG. 4 to FIG. 10 are schematic diagrams of first to seventh application scenarios of a memory access method according to embodiments of the disclosure.

### DETAILED DESCRIPTION OF THE INVENTION

The technical solutions of the embodiments of the disclosure are clearly and comprehensively described in combination with the accompanying drawings of the embodiments of the disclosure. It is obvious that the described embodiments are merely some embodiments of the disclosure but not all possible embodiments. On the basis of the embodiments of the disclosure, all other embodiments arrived by a person skilled in the art without involving inventive skills are to be encompassed within the scope of protection of the disclosure.

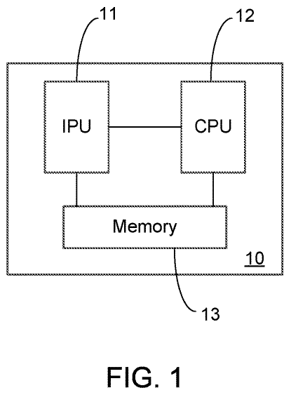

Refer to FIG. 1. FIG. 1 shows a structural schematic diagram of a chip applied to an electronic device according to an embodiment of the disclosure. A chip 10 includes an intelligent processing unit (IPU) 11, a central processing unit (CPU) 12 and a memory 13. The IPU 11 is for performing data processing, for example, image data processing, video data processing and audio data processing. The CPU 12 may be used to operate an operating system of an electronic device, and perform data operation. The memory 13 includes a memory space. The memory space may be used to store data, for example, image data and audio data, and may further be used to store data generated during operation processes of the IPU 11 and the CPU 12.

In one embodiment, the IPU 11 is integrated with a direct memory access (DMA) controller, and the IPU 11 accesses the memory 13 through the DMA controller. The DMA controller can control access or transfer of data stored in the memory 13, for example, control transfer of the data from one storage space to another storage space, or control transfer of the data from the memory 13 to another memory (such as an internal memory).

The memory 13 may include multiple types of memories, for example, random access memory (RAM), static random access memory (SRAM), and dynamic random access memory (DRAM).

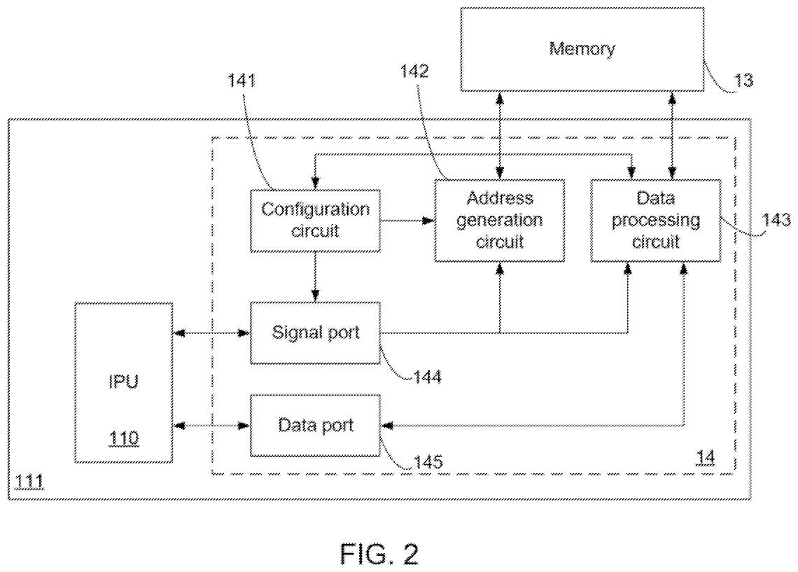

Refer to FIG. 2. FIG. 2 shows a block diagram of an intelligent processing apparatus according to an embodiment of the disclosure. An intelligent processing apparatus 111 may correspond to the IPU 11 in FIG. 1, and includes an IPU core 110 and a DMA controller 14, wherein the IPU core 110 may be regarded as a processor in the intelligent processing apparatus 111. In implementation, the IPU core 110 accesses data in the memory 13 through the DMA controller 14.

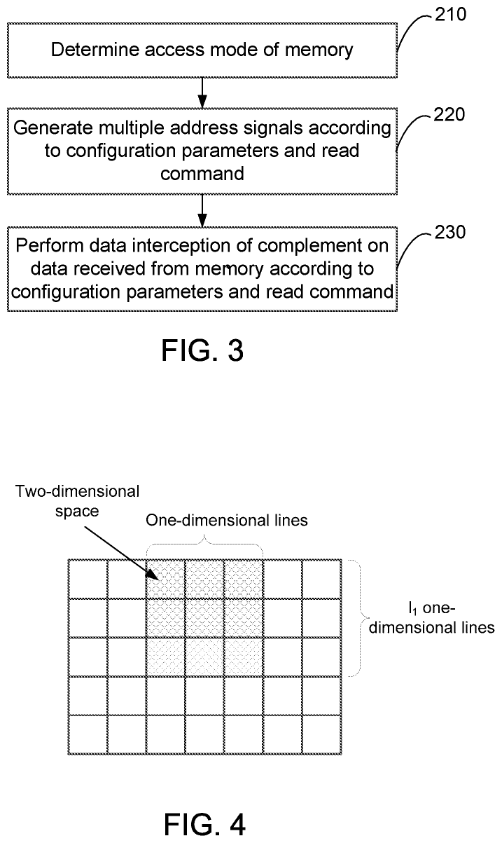

Refer to FIG. 3. FIG. 3 shows a first flowchart of a memory access method according to an embodiment of the disclosure. In this embodiment, the memory access method is performed by the intelligent processing apparatus 111, and steps of the memory access method are described in detail below.

In step 210, an access mode of the memory is determined. The DMA controller 14 is configured therein with multiple memory access modes in advance, that is, including multiple operation modes, each memory access mode corresponds to one set of configuration parameters, and the DMA controller 14 operates according to the configuration parameters. For example, a non-byte access mode and a byte access mode may be configured in advance. A corresponding mode message may be provided for each memory access mode, and the mode message may be recorded in a register, and includes, for example, an access mode command code byte_mode. For example, when the memory access mode is a non-byte access mode, byte_mode may be configured as 0; when the memory access mode is a byte access mode, byte_mode may be configured as 1.

In one embodiment, the DMA controller 14 may be further provided therein with a mode message of a memory access pattern, for example, an access pattern command code extract mode. Extract_mode=0 represents a sequential address mode, and extract_mode=1 represents a hop address access mode. The DMA controller 14 may first obtain the mode message of the memory access pattern at the beginning of execution of memory access. When the obtained mode message of the memory access pattern is extract_mode=0, the memory 13 is accessed according to a common sequential address access pattern; in this mode, an address generation circuit 142 correspondingly generates a plurality of consecutive addresses so as to access the memory 13. When the obtained mode message of the memory access pattern is extract_mode=1, the memory 13 is accessed according to a hop address access pattern; in this mode, the address generation circuit 142 correspondingly generates a plurality of address signals, which include a plurality of non-consecutive addresses. In this embodiment, the mode message of the memory access mode and the mode message of the memory access pattern determine the operation mode of the DMA controller 14, and determine the corresponding configuration parameters, and the DMA controller 14 then operates according to the configuration parameters. In practice, the DMA controller 14 includes therein a configuration circuit 141. The configuration circuit 141 provides the corresponding configuration parameters according to the current operation mode, that is, the configuration circuit 141 may provide the corresponding configuration parameters according to the mode messages of the memory access mode and the memory access pattern.

In one embodiment, the configuration parameters may include parameters such as a data bit length parameter, a data transmission length and an address hop length. The data bit length parameter includes information such as a data read/write bit length and a data transmission bit length. The data read/write bit length represents a bit length for reading a data line, and the data transmission bit length represents a bit length of data transmission during access of the memory 13.

For example, for the non-byte access mode, the data read/write bit length and the data transmission bit length are both configured as m bytes; for the byte access mode, the data read/write bit length is configured as m bytes, and the data transmission bit length is configured as one byte, where m is an integer greater than 1.

In practice, the data transmission length may include one parameter, or may include one set of parameters. Similarly, the address hop length may include one parameter, or may include one set of parameters. In one embodiment, the data transmission length includes l₀, which represents the data length of one transmission; the address hop length includes s₀, which represents the address length that needs to be hopped between one access and a next access of the memory space, where l₀ and s₀ are both positive integers.

In step 220, multiple first address signals are generated according to the configuration parameters and the read command. When the IPU core 110 is to read the data in the memory 13, the IPU core 110 generates a read command to a signal port 144 of the DMA controller 14, and the signal port 144 translates and transmits the received read command to the address generation circuit 142. The address generation circuit 142 generates multiple address signals according to the configuration parameters provided by the configuration circuit 141, and outputs the address signals to the memory 13, so as to read the corresponding data in the memory 13.

When the mode message of the memory access pattern is extract_mode=1 and the operation is in the non-byte access mode, the multiple address signals generated by the address generation circuit 142 include multiple non-consecutive address signals so as to read data corresponding to n-dimensional data blocks from the memory 13, where n is a positive integer greater than 1. Associated details are given below.

In practice, the address generation circuit 142 generates the corresponding multiple address signals according to the parameters including the data read/write bit length, the data transmission bit length, the data transmission length and the address hop length, and then according to the read command.

Refer to FIG. 4. FIG. 4 shows a schematic diagram of a first application scenario of a memory access method according to an embodiment of the disclosure. The data stored in the storage space of the memory 13 may correspond to a two-dimensional space (panel). The two-dimensional space includes l₁ one-dimensional lines, of which the data length is l₀. Each time the DMA controller 14 performs a read operation or a write operation on such type of memory space, the address generation circuit 142 generates a corresponding address signal so as to access one of the one-dimensional lines. In this embodiment, the data transmission length includes l₀ and l₁, which are one set of parameters. The address hop length includes s₀, which represents an address difference between an ending address of each one-dimensional line and a starting address of a next one-dimensional line, where l₀, l₁ and s₀ are all positive integers. Accordingly, access is performed in a way of hopping s₀ byte addresses between each one-dimensional line and a next one-dimensional line. After completing access of one-dimensional lines by means of the multiple corresponding addresses, access of the two-dimensional space is complete.

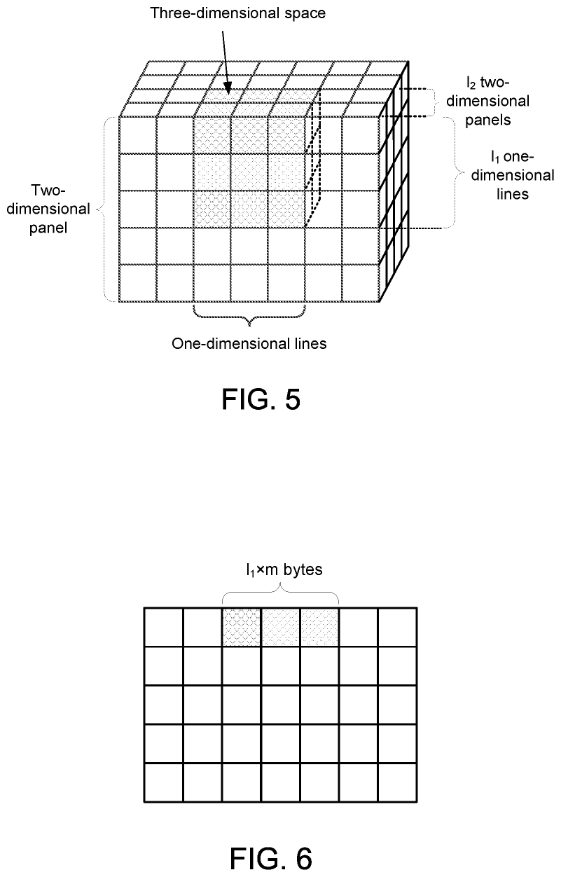

In another embodiment, refer to FIG. 5. FIG. 5 shows a schematic diagram of a second application scenario of a memory access method according to an embodiment of the disclosure. The data stored in the storage space of the memory 13 may correspond to a three-dimensional space (map). The three-dimensional space includes l₂ two dimensional spaces as shown in FIG. 4. In this embodiment, the data transmission length further includes l₂, and the address hop length further includes The address hop length s₁ represents an address difference between an ending address of each two-dimensional space and a starting address of a next two-dimensional space, where l₁, l₂ and s₁ are all positive integers. More specifically, each time the ending address of a two-dimensional space is read, the address generation circuit 142 generates a next address signal according to s₁, and accordingly, access is performed in a way of hopping s₁ byte addresses between each two-dimensional space and a next two-dimensional space. After completing access of l₂ two-dimensional spaces by means of the multiple corresponding address signals, access of the three-dimensional space is complete.

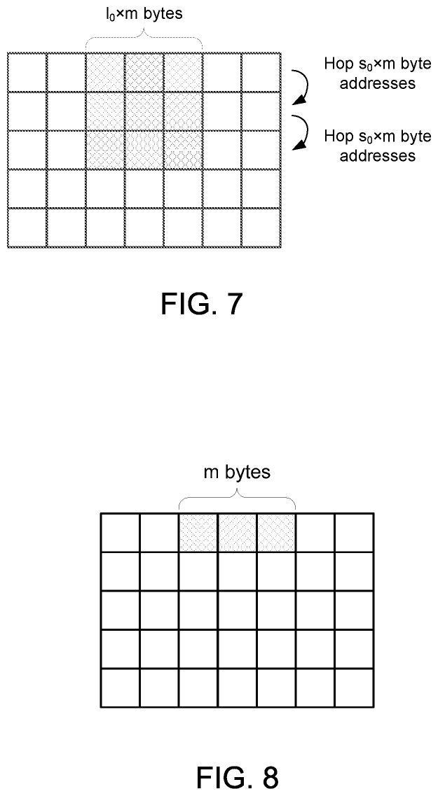

In some embodiments, refer to FIG. 6 and FIG. 7. FIG. 6 shows a schematic diagram of a third application scenario of a memory access method according to an embodiment of the disclosure. FIG. 7 shows a schematic diagram of a fourth application scenario of a memory access method according to an embodiment of the disclosure. When the operation is in the non-byte access mode, for example, when byte_mode=0, the data read/write bit length and the data transmission bit length are both m bytes. At this point, a read operation is performed on the memory space in a unit of the data read/write bit length according to the data transmission length and the address hop length, and the data read by the read operation is transmitted in a unit of the data transmission bit length according to the data transmission length; when the DMA controller 14 performs a read operation on the memory space, one one-dimensional length l₀ is read each time, and the next one-dimensional line is read in a way of hopping s₀ each time after reading one one-dimensional line. Thus, l₀×m bytes in the memory space are read each time, and the next read is performed in a way of hopping s₀×m byte addresses each time after reading s₀×m bytes. Further, each time l₀×m bytes are read, the l₀×m bytes are transmitted.

When the DMA controller 14 performs a write operation on the memory space, data of one one-dimensional line l₀ is transmitted each time and one one-dimensional line l₀ is written, and writing of the next one-dimensional line is performed in a way of hopping s₀ addresses each time after writing one one-dimensional line. Thus, l₀×m bytes are transmitted and written to l₀×m byte addresses of the memory space each time, and the next write is performed in a way of hopping s₀×m byte addresses each time after writing l₀×m bytes.

In step 230, data interception or complement is performed on the data received from the memory according to the configuration parameters and the read command. The data processing circuit 143 receives the data that the memory 13 outputs in response to the multiple first address signals generated by the address generation circuit 142, and performs a data interception or complement process on the data received from the memory according to the configuration parameters and the read command. The data processed by the data processing circuit 143 may be transmitted to the IPU core 110 through the data port 145.

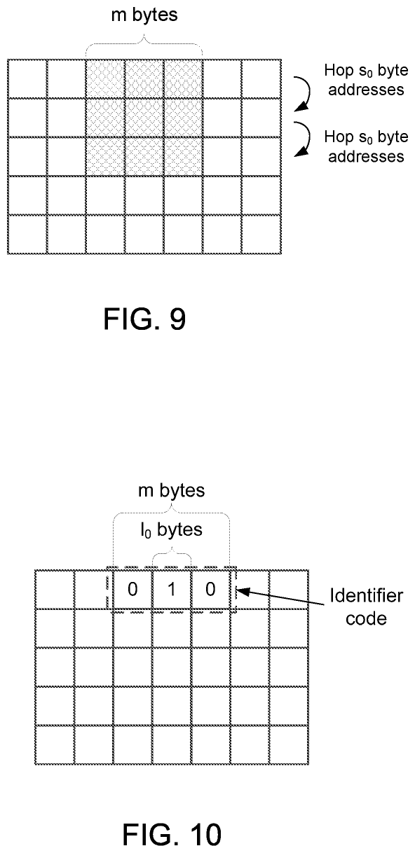

In one embodiment, refer to both FIG. 8 and FIG. 9. FIG. 8 shows a schematic diagram of a fifth application scenario of a memory access method according to an embodiment of the disclosure. FIG. 9 shows a schematic diagram of a sixth application scenario of a memory access method according to an embodiment of the disclosure. When the operation is in the byte access mode, for example, when byte_mode=1, the data read/write bit length is m bytes, and the data transmission bit length is one byte. When the DMA controller 14 receives the read command sent by the IPU core 110, the DMA controller 14 reads, by means of the address signals generated by the address generation circuit 142, m bytes in the memory space each time, and performs the next read in a way of hopping s₀ bytes each time after reading m bytes. After reading m bytes each time, that is, when the memory 13 outputs m bytes of data to the DMA controller 14 in response to the address signals, the data processing circuit 143 intercepts l₀ consecutive bytes from each m bytes that are read, and outputs the l₀ bytes to the IPU core 110 through the data port 145; it is understandable that l₀ is less than m at this point. Since the data read/write bit length is different from the data transmission bit length, the data processing circuit 143 needs to perform an interception operation on the m bytes that are read each time during data transmission.

Refer to FIG. 10. FIG. 10 shows a schematic diagram of a seventh application scenario of a memory access method according to an embodiment of the disclosure.

It is understandable that because l₀ is less than m, the m byte addresses need to be complemented each time after writing l₀ bytes into the m byte addresses of the memory space. Thus, after transmitting and writing l₀ bytes to the m byte addresses of the memory space each time, a corresponding identifier code needs to be provided while writing each set of l₀ bytes, and the byte addresses not written with any bytes in each set of m byte addresses of the memory space are complemented.

The DMA 14 may provide a corresponding identifier code each time when writing l₀ bytes to the m byte addresses of the memory space. It should be noted that, to configure the identifier code, the bytes may be first written and then the identifier code is provided, the identifier code may be first provided and then the bytes are written, or the identifier code may be provided while writing the bytes. The identifier code indicates which byte addresses of the m byte addresses are written with valid data, and which byte addresses are not yet written with valid data. The identifier code may be an m-bit binary character, a binary character of “1” represents that the located byte address is written with valid data, and a binary character of “0” represents that the locate byte address is not written with valid data. For example, as shown in FIG. 10, in the m byte addresses, the binary character of the byte addresses written with l₀ bytes may be configured as 1, and the binary characters of the byte addresses other than the byte addresses written with l₀ bytes may be configured as 0.

Moreover, the DMA controller 14 may complement the byte addresses not written with bytes in each set of the m byte addresses of the memory space, that is, complementing the byte addresses having the identifier code as the binary character 0, such as complementing to 0, or complementing to other value as desired. It is understandable that, since the binary characters of the complemented byte addresses are 0, it also means that the data at the complemented byte addresses is invalid data, and any desired value used for the complement does not affect the data written to the m byte addresses.

In some embodiments, for the byte access mode, for example, when byte_mode=1, the data read/write bit length is m bytes, and the data transmission bit length is one byte. When the data in the memory space corresponds to a three-dimensional space, the three-dimensional space includes l₂ two-dimensional spaces, with each two-dimensional space including l₁ one-dimensional lines, and the length of each one-dimensional line being l₀. The address hop length include s₀ and s₁, s₀ and s₁ are a set of parameters, each one-dimensional line and a next one-dimensional line are spaced by s₀ byte addresses, and each two-dimensional space and a next two-dimensional space are space by s₁ byte addresses.

At this point, when l₀ is less than m, the sum of l₀ and s₀ is equal to m and s₀ is less than s₁, the operation performed by the DMA controller 14 according to the configuration parameters of the operation mode includes: reading l₁×m bytes in the memory space each time, performing the next read in a way of hopping l₁×m (s₁−s₀) byte addresses each time after reading l₁×m bytes, and transmitting l₁×m bytes each time after reading l₁×m bytes.

It is understandable that, in an actual application, to perform a read operation or a write operation on a double data rate (DDR) memory, because the bus structure is an advanced extensible interface (AXI), such bus structure is capable of reading/writing multiple m bytes, and multiple read/write requests may exist simultaneously on the bus although a result of a first read/write request sent out is not yet received. Due to a delay in a read/write operation of such DDR memory, the utilization efficiency is significantly reduced if one set of m bytes is read/written each time.

Further, it is understandable that, both l₀ and s₀ are small when l₀ is less than m, the sum of l₀ and s₀ is equal to m and s₀ is less than s₁, and so if the memory space is accessed according to the byte access mode, a read operation or a write operation needs to be performed multiple times on the same m byte addresses, further leading to lowered access efficiency. When expanded to a multi-dimensional memory space, in a situation where one set of m bytes includes valid bytes at k0, k1, k2, . . . and kx sections, the address hop lengths are p0, p1, p2, . . . and px−1, respectively, and k0+p0+k1+p1+k2+p2+px−1+kx+s₀ is m, the m bytes need to be accessed for x times, and hence it is evident that the access efficiency is extremely low.

Therefore, the access mode is modified at this point to the non-byte access mode, and the length of the one-dimensional lines is modified to Ii, the number of one-dimensional lines is modified to l₂, the number of two-dimensional spaces is modified to 1, the hop address between each one-dimensional line to a next one-dimensional line is modified to s₁−s₀, the hop address between each two-dimensional space and a next two-dimensional space is modified to 0, and access is performed according to the non-byte access mode, so as to enhance the access efficiency.

That is, l₁×m bytes in the memory space are read each time, the next read is performed in a way of hopping (s₁−s₀)×m byte addresses each time after reading l₁×m bytes, and l₁×m bytes are transmitted each time after reading l₁×m bytes.

Similarly, when l₀ is less than m, the sum of l₀ and s₀ is equal to m and s₀ is less than s₁, data is transmitted in a unit of the data transmission bit length according to the data transmission length, and a write operation is performed on the memory space in a unit of the data read/write bit length according to the data transmission length and the address hop length, the operation including: transmitting and writing l₁×m bytes to l₁×m byte addresses of the memory space each time, and performing the next read in a way of hopping (s₁−s₀)×m byte addresses each time after reading l₁×m bytes.

Accordingly, access of a three-dimensional space can be hopped to access of two dimensional spaces, and access can be performed according to the non-byte mode, thereby enhancing the access efficiency of the memory space.

In one embodiment, after reading l₁×m bytes of the memory space each time, the operation further includes: determining a start byte and an end byte of each set of m bytes, wherein a byte length between the start byte and the end byte of each set of m bytes is l₀; the transmitting and writing l₁×m bytes to l₁×m byte addresses of the memory space each time includes: determining a start byte and an end byte of each set of m bytes of the memory space; transmitting l₀×m bytes each time; sequentially writing each set of l₀ bytes to each set of m byte addresses, and providing a corresponding identifier code; and complementing the byte addresses not written with bytes in each set of m byte addresses.

It is understandable that, since the access of the three-dimensional space is hopped to the access of the two-dimensional spaces, to perform a read operation, a start byte (start_byte) and an end byte (end_byte) of each set of m bytes need to be determined each time after reading l₁×m bytes of the memory space, so as to ensure the data read by the read operation, data transmitted, data written by the write operation are accurately aligned, further ensuring validity of data.

Correspondingly, to perform a write operation, the start bye and the end byte of each set of m bytes need to be first determined, l₀×m bytes are then transmitted each time, and each set of l₀×m bytes are sequentially written to one set of m byte addresses.

Moreover, a corresponding identifier code needs to be provided while writing each set of l₀ bytes, and the byte addresses not written with any bytes in each set of m byte addresses of the memory space are complemented. It should be noted that, to configure the identifier code, the bytes may be first written and then the identifier code is provided, the identifier code may be first provided and then the bytes are written, or the identifier code may be provided while writing the bytes.

Details of providing the identifier code and complementing the byte addresses may be referred from the description of the embodiments above, and are omitted herein for brevity.

In an actual implementation, the disclosure is not limited by the execution sequences of the various steps described, and without producing any conflict, some of the steps may also be performed in other sequences or performed simultaneously.

It is known from the description above, in the memory access method provided by the embodiments of the disclosure, multiple operation modes can be configured for a DMA controller, wherein the different operation modes correspond to different configuration parameters. Further, in conjunction with specific read commands, the operation mode may be set according to different memory access requirements, and a memory space may be accessed by adopting different parameters, thereby providing the memory space with more flexible and diversified accessed modes. In addition, the object of corresponding to data of n-dimensional data blocks can be achieved by involving only one read command, hence saving command resources during access of the memory space.

The memory access method and the intelligent processing apparatus provided according to the embodiments of the disclosure are as described in detail above. The principle and implementations of the disclosure are described by way of applying specific embodiments in the description, and the description of the embodiments are for better understanding of the method and core concepts of the disclosure. Further, modifications may be made to the specific implementations and application ranges by a person skilled in the art according to the concepts of the disclosure. In conclusion, the contents of the description should not be construed as limitations to the disclosure.

What is claimed is:

1. A memory access method, applied to an intelligent processing apparatus, comprising:
determining a memory access mode;
obtaining a data bit length parameter according to the memory access mode, the data bit length parameter comprising a data read/write bit length and a data transmission bit length;
obtaining a memory access parameter of a memory space, the memory access parameter comprising a data transmission length and an address hop length; and
accessing the memory space according to the data read/write bit length, the data transmission bit length, the data transmission length and the address hop length.

2. The memory access method according to claim 1, wherein the step of accessing the memory space according to the data read/write bit length, the data transmission bit length, the data transmission length and the address hop length comprises:
performing a read operation on the memory space in a unit of the data read/write bit length according to the data transmission length and the address hop length, and transmitting data read by the read operation in a unit of the data transmission bit length according to the data transmission length.

3. The memory access method according to claim 1, wherein the step of accessing the memory space according to the data read/write bit length, the data transmission bit length, the data transmission length and the address hop length comprises:
transmitting data in a unit of the data transmission bit length according to the data transmission length, and performing a write operation on the memory space in a unit of the data read/write bit length according to the data transmission length and the address hop length.

4. The memory access method according to claim 2, wherein the memory access mode comprises a non-byte access mode, the data read/write bit length and the data transmission bit length obtained according to the non-byte access mode are both m bytes, where m is an integer greater than 1.

5. The memory access method according to claim 4, wherein the step of performing the read operation on the memory space in a unit of the data read/write bit length according to the data transmission length and the address hop length, and transmitting the data read by the read operation in a unit of the data transmission bit length according to the data transmission length comprises:
reading l₀×m bytes in the memory space each time, and performing a next read in a way of hopping s₀×m byte addresses each time after reading the l₀×m bytes; and
transmitting the l₀×m bytes each time after reading the l₀×m bytes;
wherein, l₀ is the data transmission length, s₀ is the address hop length, and l₀ and s₀ are both positive integers.

6. The memory access method according to claim 1, wherein the memory space comprises a two-dimensional space, the two-dimensional space comprises l₁ one-dimensional lines, the address hop length comprises s₀, and access is performed in a way of hopping s₀ byte addresses between each one-dimensional line and a next one-dimensional line so as to complete access of the two-dimensional space, where l₁ and s₀ are both positive integers.

7. The memory access method according to claim 6, wherein the memory space comprises a three-dimensional space, the three-dimensional space comprises l₂ of the two-dimensional space, the address hop length further comprises s₁, and access is performed in a way of hopping s₁ byte addresses between each two-dimensional space and a next two-dimensional space so as to complete access of the three-dimensional space, where l₂ and s₁ are both positive integers.

8. An intelligent processing apparatus, comprising:
a processor, generating a read command to read data from a memory; and
a direct access memory (DMA) controller, reading data from the memory according to the read command, the DMA controller comprising:
a configuration circuit, providing a first configuration parameter according to a first operation mode;
a signal port, receiving the read command;
an address generation circuit, generating a plurality of first address signals to the memory according to the first configuration parameter and the read command;
a data processing circuit, receiving data that the memory outputs in response to the first address signals, and performing a data interception process on the data received from the memory according to the read command and the first configuration parameter; and
a data port, transmitting the data processed by the data processing circuit to the processor;
wherein, the first address signals comprise a plurality of non-consecutive address signals such that the data read from the memory and processed by the data processing circuit corresponds to n-dimensional data blocks, where n is a positive integer greater than 1.

9. The intelligent processing apparatus according to claim 8, wherein the first configuration parameter comprises a data transmission length and an address hop length.

10. The intelligent processing apparatus according to claim 8, wherein the configuration circuit provides a second configuration parameter according to a second operation mode; and the address generation circuit generates a plurality of second address signals to the memory according to the second configuration parameter, wherein the second address signals are consecutive address signals.

11. A memory access method, applied to an intelligent processing apparatus, the intelligent processing apparatus comprising a processor, the memory access method comprising:
receiving a read command from the processor to read data from a memory;
providing a first configuration parameter according to a first operation mode;
generating a plurality of first address signals to the memory according to the first configuration parameter and the read command; and
receiving data that the memory outputs in response to the first address signals, and performing a data interception process on the data received from the memory according to the read command and the first configuration parameter to output to the processor;
wherein, the first address signals comprise a plurality of non-consecutive address signals such that the data read from the memory and processed by the data processing circuit corresponds to n-dimensional data blocks, where n is a positive integer greater than 1.

12. The memory access method according to claim 11, wherein the first configuration parameter comprises a data transmission length and an address hop length.

13. The memory access method according to claim 11, further comprising:
providing a second configuration parameter according to a second operation mode; and
generating a plurality of second address signals to the memory according to the second configuration parameter, wherein the plurality of second address signals are consecutive address signals.
